(19) United States
(12) Patent Application Publication
(10) Pub. No.: US 2015/0323575 A1
(43) Pub. Date: Nov. 12, 2015

(54) ESTIMATING AN ELECTRICITY SUPPLY'S FUNDAMENTAL FREQUENCY

(71) Applicant: ITRON FRANCE, Issy-Les-Moulineaux, Paris (FR)

(72) Inventors: Gwladys Fabienne Alice CHANEDEAU, Blaslay (FR); Jean-Paul GAUBERT, Poitiers (FR); Jean-Francois TISSIER, Chasseneuil du Poitou (FR)

(21) Appl. No.: 14/650,825

(22) PCT Filed: Oct. 17, 2013
(86) PCT No.: PCT/EP2013/071709

§ 371 Date: Jun. 9, 2015

(30) Foreign Application Priority Data
Dec. 10, 2012 (EP) 12306558.3

(51) Int. Cl. G01R 23/02

(52) U.S. Cl. CPC G01R 23/02

(57) ABSTRACT

This disclosure relates to an apparatus, computer readable medium and a method for estimating a frequency of an electrical signal. The method comprises converting a first signal having three components into a second signal having two components in accordance with a first transformation, wherein each component of the first signal corresponds to a phase component of a three-phase electrical signal and the two components of the second signal are representative of characteristics of the three-phase electrical signal. The method further comprises filtering the second signal in accordance with a previous frequency estimation. Then the method comprises converting the filtered second signal into a third signal having a single component in accordance with a second transformation, wherein the single component of the third signal is representative of characteristics of the three-phase electrical signal. Finally, the method comprises estimating a frequency of the third signal, wherein the estimated frequency of the third signal is indicative of a frequency of the three-phase electrical signal.

### FIELD OF INVENTION

The present disclosure relates to frequency estimation of an electrical signal. More specifically, but not exclusively, the present disclosure provides a means for estimating a frequency at a point within an electricity grid network.

### BACKGROUND TO THE INVENTION

Stability of electricity grids is extremely important in the developed world where so much of everyday life relies upon an electricity supply. If electricity supplied by electricity grid is unstable then there is high risk of a blackout occurring, which in some circumstances can result in large areas of a country, or even continent, losing power for relatively long periods of time. While blackouts are a general annoyance to everyone in a blackout zone, they also have an economic effect on businesses in the blackout zone and beyond.

In order to help prevent blackouts occurring it is necessary to precisely monitor the frequency of electricity being supplied by an electricity grid in order to detect unusual fluctuations in the electricity supply. Since abnormal excursions of the fundamental frequency of the electricity supply and the rate of change of the electricity supply outside of the normal limits usually occur just before a blackout, not only the accuracy of the frequency analysis, but the speed of the frequency analysis is of utmost importance. The frequency analysis is carried out by frequency protection relays installed in medium voltage (MV) or high voltage (HV) substations so that if a problem is detected the power can be cut off at those substations and thereby prevent damage to devices supplied via that substation.

While these protection relays operate relatively quickly, usually in less than 5 seconds of the frequency drifting out of normal operating conditions, this unfortunately results in large areas of the network being cut off. Furthermore, the classical methods to estimate the fundamental frequency and the rate of change of frequency of an electrical signal are complex and therefore computationally expensive.

With the future of electricity supply looking to become more reliant on smart grids with electricity being supplied from a large range of sources with differing power levels, the problem of managing electricity supply throughout a network will be more challenging. New ranges of smart meters may help with such problems because the smart meters themselves include a disconnecting switch in series with the supply to and from the grid. Consequently, network control can be provided throughout the grid from a remote central controller. However, when time for delivery of network communications also has to be taken into account, in addition to the processing resources available on smart meters, it is important that the speed at which an accurate frequency estimate is obtained is increased.

### SUMMARY OF INVENTION

Embodiments of the present invention attempt to mitigate at least some of the above-mentioned problems.

In accordance with an aspect of the invention there is provided a method for estimating a frequency of an electrical signal. The method comprises converting a first signal having three components into a second signal having two components in accordance with a first transformation. Each component of the first signal corresponds to a phase component of a three-phase electrical signal and the two components of the second signal are representative of characteristics of the three-phase electrical signal. The method further comprises filtering the second signal in accordance with a previous frequency estimation. The method also comprises converting the filtered second signal into a third signal having a single component in accordance with a second transformation. The single component of the third signal is representative of characteristics of the three-phase electrical signal. The method further comprises estimating a frequency of the third signal. The estimated frequency of the third signal is indicative of a frequency of the three-phase electrical signal.

The filtering may comprise applying a band pass filter to the second signal, the band pass filter being centred on the frequency of a previous frequency estimation. The band pass filter may be arranged to apply unity gain and zero phase shift at the frequency of the previous frequency estimation.

The method may further comprise feeding back the current frequency estimation for filtering the next frequency estimation.

The first transformation may be a Concordia transformation. The Concordia transformation may be defined by:

$$[ \begin{matrix}{V}_{α} \\ {V}_{β}\end{matrix} ] = \sqrt{\frac{2}{3}} [ \begin{matrix}1 & - \frac{1}{2} & - \frac{1}{2} \\ 0 & \frac{\sqrt{3}}{2} & - \frac{\sqrt{3}}{2}\end{matrix} ] [ \begin{matrix}{V}_{a} \\ {V}_{b} \\ {V}_{c}\end{matrix} ]$$

wherein Vₐ, V_{b}, V_{c} are the three components of the first signal and V_{α} and V_{β} are the two components of the second signal.

The second transformation may utilise a previous estimation of a phase of the three-phase electrical signal.

The second transformation may be a Park transformation. The Park transformation may be defined by:

$$[ \begin{matrix}{V}_{d} \\ {V}_{q}\end{matrix} ] = [ \begin{matrix}cos ( \hat{θ} ) & sin ( \hat{θ} ) \\ - sin ( \hat{θ} ) & cos ( \hat{θ} )\end{matrix} ] [ \begin{matrix}{V}_{α} \\ {V}_{β}\end{matrix} ]$$

wherein V_{α} and V_{β} are the two components of the second signal after being filtered, \hat{θ} is a previous estimation of a phase of the three-phase electrical signal, and V_{d} and V_{q} are outputs of the second transformation, wherein V_{d} is forced to zero and V_{q} therefore corresponds to the third signal.

The frequency may be estimated by estimating a phase of the third signal and estimating the frequency of the third signal in accordance with the estimated phase.

The phase may be estimated using a phase locked loop. The phase locked loop may comprise a loop filter arranged to estimate an angular frequency of the signal having a single component and a voltage controlled oscillator arranged to estimate the phase of the estimated angular frequency.

The method may further comprise feeding back the estimated phase to the second transformation for estimating a next phase.

The method also further comprise calculating the average frequency over a period of time. A plurality of frequency estimations may be made during the period of time.

The method may further comprise determining an error level in the frequency estimation and excluding any frequency estimations from the average frequency calculation having an error level greater than an error threshold.

The method may further comprise determining a rate of change of frequency from the average frequency.

The method may also further comprise measuring the three components of the three-phase electrical signal. The measurement may comprise measuring voltages of the three-phase electrical signal.

The method may further comprise converting a single-phase electrical signal into the three-phase electrical signal in accordance with a third transformation before converting the three-phase signal in accordance with the first transformation.

In accordance with a further aspect of the invention there is provided apparatus for estimating a frequency of an electrical signal, the apparatus arranged to implement any method as described herein.

The apparatus may be an electricity meter. The electricity meter may further comprise a sensor arranged to measure one or more characteristics of an electrical signal, a memory arranged to store the one or more characteristics of the electrical signal and store a computer program for implementing the method, a processor arranged to perform the method in accordance with the stored characteristics of the electrical signal and the computer program, and a communications unit arranged to transmit information relating to the frequency estimation to a central server.

In accordance with yet another aspect of the invention there is provided a computer readable medium comprising computer readable code operable, in use, to instruct a computer to perform any of the methods described herein.

Embodiments of the invention provide a robust algorithm calculating the main frequency, the average value of the fundamental frequency and the rate of change of the fundamental frequency per cycle using samples of the electrical grid voltages or currents of an electricity meter. The algorithm may be embedded inside the metrology firmware of an electricity meter. The algorithm may take into account the technical capabilities of smart meters for improved performance.

Algorithms provided in accordance with embodiments of the invention are compatible with the sampling rate in the kHz range used by electricity meters. In addition, such algorithms are operational for single phase or poly phase electricity supplies.

Embodiments of the invention improve the accuracy of estimating the fundamental frequency of an electrical signal and the insensitivity of such a signal to perturbations of waveforms, such as harmonics in an unbalanced three phase system. For example, a constant change of 2 millihertz per cycle of a 50 Hz waveform may produce a rate of change of 0.1 Hz per second.

Embodiments of the invention provide frequency estimation with accuracy better than +/−1 millihertz.

Embodiments of the invention estimate the fundamental frequency at the sampling frequency of the electricity meter and determine the rate of change of the fundamental frequency on each cycle of the main frequency. These parameters may be determined within a smart meter.

Embodiments of the invention provide a smart meter associated with a switch in series with the power supply arranged to disconnect the load connected to the smart meter from the power supply when conditions of instability of the fundamental frequency are detected. The instability may be detected by the smart meter. The instability may be detected by a remote device, which remotely controls the disconnection of the load connected to the smart meter. The conditions for disconnecting the load directly at the smart meter may be the accuracy, the reliability and/or the speed of the detection of the fundamental frequency and/or the rate of change of the fundamental frequency. The system may be arranged so that the disconnection takes place at the smart meter if and only if the disconnection at the smart meter is faster, more accurate and robust in stabilizing the frequency than performing a disconnection at the MV substation. It will be appreciated that in some embodiments the switch is incorporated within the smart meter, while in alternative embodiments the switch may be separate from the meter and controlled by the smart meter.

Advantageously, embodiments of the invention may perform preventive shedding quick enough to avoid a bulk regional blackout from HV/MV substations.

In embodiments of the invention, a decision regarding a disconnection at a meter may be a local decision taken prior to transmission of data to a central server for a global decision to be made.

Conveniently, an algorithm for controlling the operation of a smart meter as disclosed herein may be embedded in the firmware of an electricity meter.

In embodiments of the invention, data samples of a voltage and/or a current of the electricity meter may be used as inputs for estimation of the fundamental frequency. In a polyphase system, the three phase voltages or the three phase currents may be utilized.

Embodiments of the invention estimate the fundamental frequency with high accuracy (e.g. +/−1 milliHertz). The sampling frequency is the sampling frequency of the metrology firmware. The rate of change of the fundamental frequency may be evaluated per fundamental cycle. A couple of estimated quantities, such a frequency and rate of change of frequency may be constituted per cycle. This couple of results may be used for detecting of network frequency instability as an embedded function of detection of pre-blackout conditions that is an abnormal excursion of the couple of parameters, frequency and rate of change of frequency, outside of a boundary.

Embodiments of the invention use a phase locked loop (PLL) to estimate the phase and/or frequency. The PLL may provide feedback control of the phase angle relative to a reference angle. The PLL may include one or more of a phase detector, a loop filter, a controlled oscillator and a single or three phases signal input. The input may be a current or three phases currents. The input is preferably a voltage. Or a three phases voltage.

Embodiments of the invention use a Concordia transformation to transform a three-phase signal into two parts. Embodiments of the invention use a Park transformation to transform a two part signal into a single part signal.

Advantageously, embodiments of the invention use a PLL which is capable of behaving correctly for purely sinusoidal signals and input signals having strongly deformed harmonics or transients. Consequently, embodiments of the invention reduce unwanted oscillations that may occur due to deformed harmonics and/or input signals. Embodiments of the invention are therefore capable of accurately estimating the fundamental frequency and rate of change of the fundamental frequency when such input conditions are present on the electrical grid waveforms.

Embodiments of the invention provide a phase locked loop (PLL) scheme which is the cooperation inside a closed loop at the sampling rate of a PLL and two adaptive modules. The first adaptive module may be an adaptive multi variable band pass filter. The adaptation of the parameters of the band pass filter may be performed in real time in the loop by reinjection of the estimated frequency inside the band pass filter transfer function. This highly selective filter has the advantage of maintaining the amplitude of the processed signal without introducing any phase shift of the instantaneous frequency, which is updated at each sample. The second adaptive module may be the injection of the estimated phase angle inside the regulation loop.

Embodiments of the invention use adaptive filters and transformations that are recalculated at each sample, which assures the robustness and accuracy of the fundamental frequency tracking.

Embodiments of the invention provide an algorithm that can be implemented in a smart meter on the basis of a sampled signal of single- or poly-phase electrical signal at a relatively low rate (e.g. in the kHz range) allowing an accurate and robust estimate of the fundamental frequency of the electrical grid and the rate of change of the fundamental frequency per cycle. The algorithm may also be designed for a single phase or poly-phase input signal, offering the same accuracy for frequency estimation at the sampling frequency of the metrology and its rate of change of the fundamental frequency at each cycle.

Embodiments of the invention also allow for different types of treatment of the calculated data inside the meter. For example, some embodiments of the invention register the maximum and minimum values of frequency and of the frequency derivative. Furthermore, some embodiments of the invention present frequency as a function of the time, the derivative of the frequency as a function of the time, as well as frequency and its derivative as 2D or 3D graphics.

Advantageously, less memory needs to be transmitted to a central server. The central server can therefore have a reduced memory size. This is because the fundamental frequency can be calculated at the sampling frequency and the rate of change of the fundamental frequency may be determined per cycle. These two values are usually inside normal limits. Consequently, the meter need not store these values in its memory. In reality only a limited volume of data may be stored in the meter and can be transmitted to the central server. For example, only the extreme values (e.g.

$${f}_{min} or {f}_{max} or \frac{df}{{dt}_{min}} or \frac{df}{{dt}_{max}} )$$

per day need be stored.

Since the algorithm provided in accordance with embodiments of the invention can utilize the hardware of known electricity meters the present invention advantageously provides limited increase in the cost of an electricity meter.

Embodiments relate to a metrology firmware of an electricity meter which can work both on a time axis and on a frequency axis. This combination of a metrological firmware working at the sampling frequency of the meter on these two axes is an advantageous feature of such embodiments.

When working in the time domain, static electricity meters according to embodiments of the invention use sampled values of V (t) (single-phase or three-phase voltages) and I(t) (phase currents(s)). The sampling frequency Fs is a constant frequency. The cumulative products of Vi(nTs).Ii(nTs) by Ts (the sampling period) determines the active power: dPactive=Vi.Ii.Ts. The 50/60 Hz reactive power is then obtained in the same manner via a rotation of 90° of the current waveform (a numerical filter provides this phase rotation at 50/60 Hz). The time domain is also used to determine the periods for calculating rms values of voltage and current (2 cycles to 1 second) and apparent power and energy Vrms.Irms.

When working in the frequency domain, the principle of embodiments of the invention is to provide a very precise sample of the fundamental frequency (e.g. +/−1 mHz provides a relative accuracy of +/−0.002%)._A software sensor obtains a signal representative of the AC network from sampled data of the voltage waveform(s). Consequently, a metrology computing with sampled values of V (t) and I (t) and an estimated value of f (t) is obtained.

The principle of such embodiments of the invention opens the way for accurate monitoring of the fundamental frequency and its stability with software implemented in the electricity meter, but also opens the way to all digital calculations like Discrete Fourier Transform (DFT). For example, extraction of amplitudes and phases of the fundamental and harmonics of all measured waveforms is possible. These calculations can be done directly from the signal, alternatively these windows can be discontinuous, or the calculations can also be done using a sliding window having a minimum length equal to one cycle of a fundamental cycle.

A real-time and highly accurate estimation of the fundamental frequency opens the way for the analysis of harmonic rank powers (active, reactive, apparent). The harmonic powers can be estimated precisely at a metering point and then correlated between different metering points connected to the same utility electrical grid to achieve the goal of quantifying the responsibility of each site in the global harmonic pollution of the grid.

### BRIEF DESCRIPTION OF THE DRAWINGS

Exemplary embodiments of the invention shall now be described with reference to the drawings in which:

FIG. 1 illustrates an electricity grid according to an embodiment of the invention;

FIG. 2 illustrates a smart meter for use in the electricity grid of FIG. 1;

FIG. 3 provides a schematic illustration of an algorithm for estimating the fundamental frequency and rate of change of the fundamental frequency of an electrical signal at the smart meter of FIG. 2;

FIG. 4 illustrates the rate of change of frequency, as a function of frequency, for the excursion of the fundamental frequency for the well-known major European grid disturbance on 4 Nov. 2006;

FIG. 5 provides a three dimensional graphical representation of the disturbance shown by FIG. 4 in terms of the rate of change of frequency, as a function of frequency, and time;

FIG. 6 illustrates the variation of frequency over time for the disturbance shown in FIGS. 4 and 5 as computed with the algorithm of FIG. 3;

FIG. 7 illustrates the variation of frequency over time for the disturbance shown in FIGS. 4 and 5 as measured in the field; and

FIG. 8 illustrates the error between the estimated frequency measurements shown in FIG. 6 with respect to the field measurements shown in FIG. 7.

Throughout the description and the drawings, like reference numerals refer to like parts.

### Specific Description

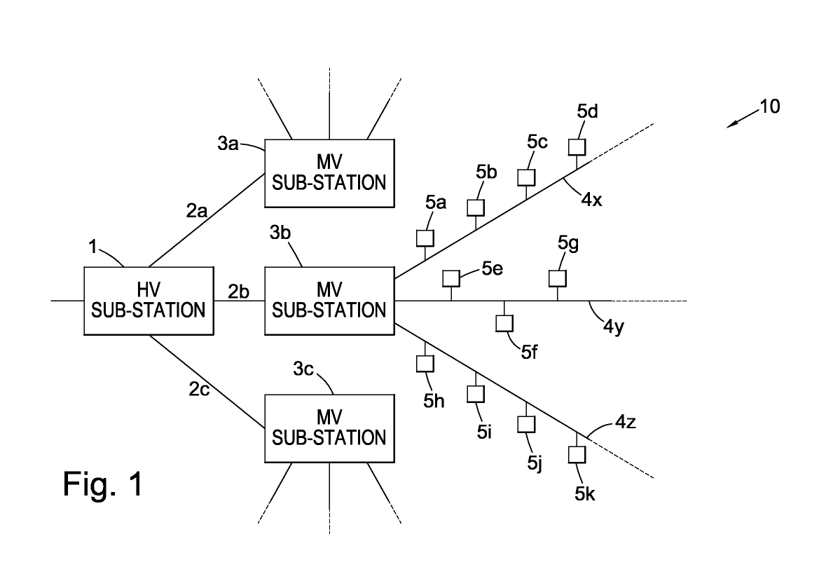

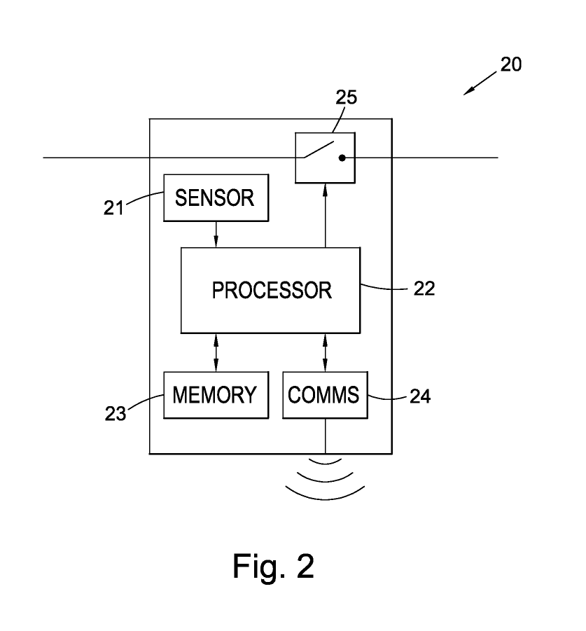

FIG. 1 illustrates an electricity grid 10 according to an embodiment of the invention. A power supply generated at a power station (not shown) is received at a high voltage (HV) substation 1 where the voltage is stepped down for further distribution. The reduced voltage power is then transmitted via connections 2a, 2b and 2c to medium voltage (MV) substations 3a, 3b and 3c where the voltage is then stepped down further for local distribution. Each of the MV substations then supplies electricity to a number of distribution lines each having a number of loads connected. For example, MV substation 3b supplies three supply lines 4x, 4y, 4z each having a number of loads 5a-5k connected thereto. One or more of the loads 5a-5k have a smart meter (not shown) connected between the supply line 4x, 4y, 4z and the respective load 5a-5k. One such smart meter is shown in FIG. 2, which is discussed in more detail below.

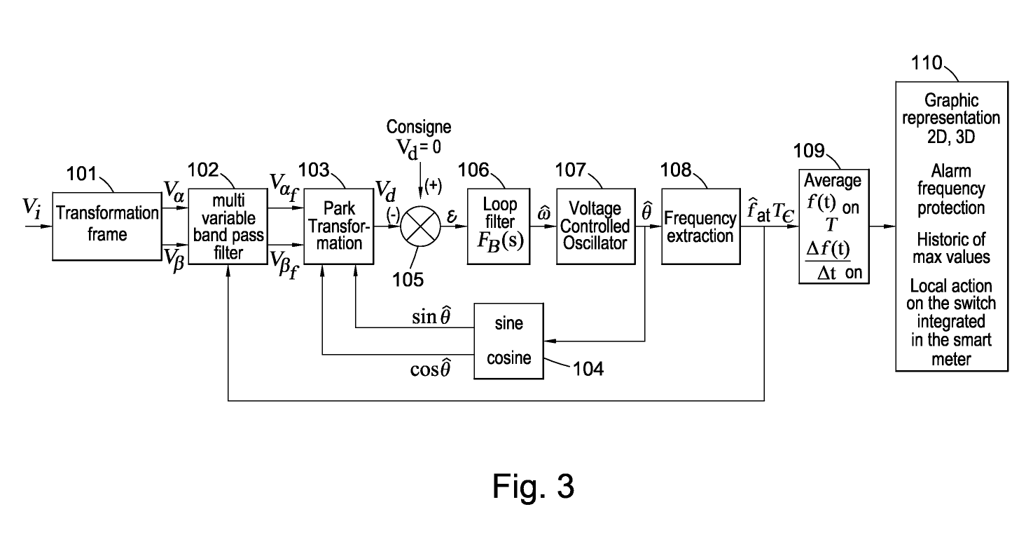

FIG. 2 illustrates smart meter 20 for use in the electricity grid 10. The smart meter 20 is arranged to monitor the electricity being drawn by a load to which it is connected via a sensor 21 and a processor 22. The sensor 21 measures either a current and/or a voltage of the electricity supply. Preferably, the smart meter has a current sensor and voltage sensor between each phase supply along with a reference potential which can act as the neutral terminal. The processor 22 then stores these measurements in internal memory 23 and feeds the measurements back to a central server via a communications unit 24. The smart meter 20 also comprises a switching unit that is capable of disconnecting the load from the grid 10. The smart meter 20 is arranged to disconnect the load in response to instructions received from the central server via the communications unit 24, or if the processor 22 determines that characteristics of the power supply could result in damage to the load. The smart meter 20 is therefore also arranged to monitor characteristics of the electricity supply. The method by which the processor 22 monitors the electricity supply and determines whether the electricity supply could cause damage to load is set-out below with reference to FIG. 3.

FIG. 3 provides a schematic illustration of an algorithm for estimating the fundamental frequency of an electrical signal at the smart meter. The algorithm is stored within the memory 23 of the smart meter 20 and implemented in the processor 22 of the smart meter 20. While the description of the algorithm provided herein is for use in a smart meter, it will be appreciated that the algorithm could be utilized for frequency estimation at any node within an electricity grid, such as at a substation.

The algorithm utilizes a closed phase-locked loop (PLL), 100, and the algorithm comprises a number of processing blocks. Each of the processing blocks shall now be described in turn.

The input to the system is a three-phase electrical input. In particular, the input derives from a measurement at the node of a three-phase voltage. It will be appreciated that in alternative embodiments of the invention a three-phase current measurement is provided as the input. However, a voltage input is preferable because a voltage input has a lower harmonic distortion (THD) than a current input.

Block 101 includes a Concordia transform, the operation of which shall now be described. Three-phase voltages are received with voltage signals Vₐ, V_{b}, V_{c}. These three-phase voltages can be represented in terms of the rms voltage and the phase or the angular frequency, as shown by Equation 1:

$$[ \begin{matrix}{V}_{a} \\ {V}_{b} \\ {V}_{c}\end{matrix} ] = \sqrt{2} {V}_{eff} [ \begin{matrix}sin ( θ ) \\ sin ( θ - \frac{2 π}{3} ) \\ sin ( θ + \frac{2 π}{3} )\end{matrix} ] = \sqrt{2} {V}_{eff} [ \begin{matrix}sin ( ω t ) \\ sin ( ω t - \frac{2 π}{3} ) \\ sin ( ω t + \frac{2 π}{3} )\end{matrix} ] \qquad Equation 1$$

Wherein V_{eff} is the rms voltage of the signals, θ is the phase of the signals ω is the angular frequency of the fundamental frequency where ω=2πF.

The Concordia transformation then transforms the three input parameters into two output parameters V_{α} and V_{β} as depicted by the matrix shown by equation 2:

$$[ \begin{matrix}{V}_{α} \\ {V}_{β}\end{matrix} ] = \sqrt{\frac{2}{3}} [ \begin{matrix}1 & - \frac{1}{2} & - \frac{1}{2} \\ 0 & \frac{\sqrt{3}}{2} & - \frac{\sqrt{3}}{2}\end{matrix} ] [ \begin{matrix}{V}_{a} \\ {V}_{b} \\ {V}_{c}\end{matrix} ] \qquad Equation 2$$

By substituting, in Equation 2, the expressions of the three signals of Equation 1, the expression of V_{α} and V_{β} can be provided as shown by Equation 3:

$$[ \begin{matrix}{V}_{α} \\ {V}_{β}\end{matrix} ] = [ \begin{matrix}\sqrt{3} {V}_{eff} sin ( θ ) \\ - \sqrt{3} {V}_{eff} cos ( θ )\end{matrix} ] \qquad Equation 3$$

The general formulation of a three-phase voltage system includes a direct rotating component, an inverse rotating component, and a homopolar component. The Concordia transformation eliminates the influence of the homopolar component and treats the direct and inverse rotating components of the signal identically. The expressions of V_{α} and V_{β} are therefore a linear sum of the direct and inverse components. The two-phase transformed components can be considered a two-phase orthogonal time varying coordinate representation of the three-phase components of the signal.

In alternative embodiments of the invention the smart meter may be connected to a single-phase electricity supply. If a single-phase input is received, Second Order Generalized Integrator (SOGI) system is utilized to transform the single phase voltage or current to the orthogonal V_{α} and V_{β} representation. The transformation of the SOGI system is shown in equation 4:

$$\{ \begin{matrix}\frac{{V}_{α} ( s )}{{V}_{i} ( s )} = \frac{K ω s}{{s}^{2} + K ω s + {ω}^{2}} \\ \frac{{V}_{β} ( s )}{{V}_{i} ( s )} = \frac{K {ω}^{2}}{{s}^{2} + K ω s + {ω}^{2}}\end{matrix} \qquad Equation 4$$

Wherein Vᵢ(s) is the input voltage, V_{α}(s) and V_{β}(s) are the output voltages, K is the gain, ω is the angular frequency, and s is the Laplace parameter.

The output of block 101 is then received by the band pass filter block 102, wherein a band pass filter is applied to the V_{α} and V_{β} components. This filtering process helps to provide robustness against disturbances of signals network waveforms.

The multi-variable filter 102 is a band pass filter with a selective adjustment parameter k which allows the filter to compromise between sensitivity (e.g. noise influence) and dynamic performance (e.g. time response). The selective adjustment parameter k is a parameter indicative of the estimated fundamental frequency, which is fed back from the previous frequency estimation at the output of the overall system.

The filter is arranged so that for the reference frequency:
Unity gain is provided, H (s)=0 dB, to guarantee the conservation of the amplitude of the input signals to the output; and
the phase of the reference frequency is not altered by ensuring that there is a zero phase shift, which thereby avoids phase perturbation of what is estimated to be the fundamental frequency.

In other words, the filter is arranged to maintain the fundamental frequency in its proper form and filter out noise, which may affect the quality and accuracy of the frequency estimation. The frequency feedback inside the regulation loop guarantees the tuning of the multi variable filter at each sampling period. Consequently, at the sampling instant tₙ, the multivariable filter is tuned by the frequency estimated at time tₙ₋₁.

This expression of the transfer function of the multi variable band pass filter is obtained in a fix reference V_{α} and V_{β}:

$$\{ \begin{matrix}{V}_{{α}_{—} f} ( s ) = \frac{k}{s} [ {V}_{α} ( s ) - {V}_{{α}_{—} f} ( s ) ] - \frac{{ω}_{c}}{s} {V}_{{β}_{—} f} ( s ) \\ {V}_{{β}_{—} f} ( s ) = \frac{k}{s} [ {V}_{β} ( s ) - {V}_{{β}_{—} f} ( s ) ] - \frac{{ω}_{c}}{s} {V}_{{α}_{—} f} ( s )\end{matrix} \qquad Equation 5$$

Wherein V_{α} and V_{β} are coordinates in a stationary reference frame; V_{α}_{_{—}}_{f} and V_{β}_{_{—}}_{f} are coordinates in a stationary reference frame at multi variable band pass filter output, ω_{c} represents the central pulsation, and the parameter k sets the filter selectivity.

After being filtered, the components V_{α} and V_{β} are then transformed again using the Park transformation block 103. The Park transformation utilizes the matrix shown in equation 6:

$$[ \begin{matrix}{V}_{d} \\ {V}_{q}\end{matrix} ] = [ \begin{matrix}cos ( \hat{θ} ) & sin ( \hat{θ} ) \\ - sin ( \hat{θ} ) & cos ( \hat{θ} )\end{matrix} ] [ \begin{matrix}{V}_{α} \\ {V}_{β}\end{matrix} ] \qquad Equation 6$$

Wherein \hat{θ} is an estimated phase angle, V_{d} and V_{q} are components of synchronous reference, i.e. the angular rotating speed that is the same as the angular speed of the input signal. The definitions of V_{α} and V_{β} depicted in Equation 3 can then be inserted into Equation 6 to provide the following definition of V_{d} and V_{q}:

$$[ \begin{matrix}{V}_{d} \\ {V}_{q}\end{matrix} ] = \sqrt{3} {V}_{eff} [ \begin{matrix}sin ( θ - \hat{θ} ) \\ - cos ( θ - \hat{θ} )\end{matrix} ] \qquad Equation 7$$

Wherein V_{eff} is the RMS voltage value of the signal, θ is a real phase angle, \hat{θ} is an estimated phase angle, V_{d} and V_{q} are components of synchronous reference.

The estimated phase angle used in Equation 7 is fed back from the output of the voltage controlled oscillator 107 via block 104, which provides sine and cosine expressions of the estimated angle.

The estimated phase angle \hat{θ} should be very close to the real phase angle. Consequently, the component V_{d} converges to 0. Hence, as shown by block 105, V_{d} is assumed to be zero in order to provide an output of V_{d} alone. On this basis, Equation 7 can be rewritten as:

V_{d}=\sqrt{3}V_{eff}(θ−\hat{θ}) Equation 8

Where V_{eff} is the RMS voltage value of the signal, θ is a real phase angle, \hat{θ} is an estimated phase angle

The output of block 105, ε, where ε=V_{dsetpoint}−V_{d} is received by the loop filter block 106. The loop filter (LF) is a proportional and integral (PI) controller. The input of the loop filter is the error (ε) and the output of the loop filter is the estimated angular frequency, \hat{ω}. The parameters of the PI controller are determined through an analysis of the transfer function of the global closed loop. As will be seen below, the general formula of the loop filter is a second order filter.

The successive use of the two transforms, Concordia and then Park, along with the loop filter provides a simple and computationally cheap means for extracting the angular frequency from a signal. Furthermore, if the same filtering were applied to the signals Vₐ, V_{b}, V_{c} three filters would be required to achieve the same functionality. Hence, the implementation of this filter by use of Vα and Vβ simplifies the filter implementation.

The loop filter F_{B}(s) associated with the PLL can be reduced to a PI filter. The associated transfer function is shown by Equation 9:

$${F}_{B} ( s ) = {k}_{p} + \frac{{k}_{i}}{s} = {k}_{p} ( \frac{1 + {τ}_{i} s}{{τ}_{i} s} ) \qquad Equation 9$$

Wherein kₚ is a proportional function, kᵢ is the Integral gain, τᵢ is a time constant, and s is the Laplace parameter.

The estimated angular frequency \hat{ω} is the derivative of the instantaneous estimation of the phase angle \hat{θ} as shown by Equation 10:

$$\hat{ω} = \frac{d \hat{θ}}{dt} \qquad Equation 10$$

The estimated angular frequency can also be expressed as a function of the loop filter F_{B}(s) and of the V_{d} component, as shown by Equation 11:

$$\hat{ω} = {F}_{B} ( s ) * {V}_{d} = {k}_{p} ( \frac{1 + {τ}_{i} s}{{τ}_{i} s} ) * \sqrt{3} {V}_{eff} ( θ - \hat{θ} ) \qquad Equation 11$$

Wherein the loop filter can be defined by developing the closed loop expression of the function F_{BF}(s) of

$$\frac{\hat{θ} ( s )}{θ ( s )} \text{:}$$

as shown in Equation 12:

$${F}_{BF} = \frac{\hat{θ} ( s )}{θ ( s )} = \frac{{k}_{p} ( \frac{1 + {τ}_{i} s}{{τ}_{i} s} ) * \sqrt{3} {V}_{eff} * \frac{1}{s}}{1 + {k}_{p} ( \frac{1 + {τ}_{i} s}{{τ}_{i} s} ) * \sqrt{3} {V}_{eff} * \frac{1}{s}} \qquad Equation 12$$

A second order transfer function can then be determined, which is written in the form shown in Equation 13:

$$\frac{\hat{θ} ( s )}{θ ( s )} = \frac{2 {ξω}_{n} s + {ω}_{n}^{2}}{{s}^{2} + 2 {ξω}_{n} s + {ω}_{n}^{2}} \qquad Equation 13$$

Wherein ωₙ is the angular frequency, ξ is the damping term, \hat{θ} is an estimated phase angle, θ(s) is a real phase angle.

The parameters kₚ and τᵢ of the loop filter F_{B}(s) depend on terms ξ and ωₙ as defined by Equations 14 and 15:

$$\begin{matrix}{k}_{p} = \frac{2 {ξω}_{n}}{\sqrt{3} {V}_{eff}} & Equation 14 \\ {τ}_{i} = \frac{2 ξ}{{ω}_{n}} & Equation 15\end{matrix}$$

The estimated angular frequency which has been determined from the loop filter stage is then integrated by a Voltage Controlled Oscillator at block 107, as discussed below.

The Voltage Controlled Oscillator 107 is effectively an integrator that converts the angular frequency into a corresponding phase angle:

$$θ = ω . t et d θ = ω . d t so \frac{d θ}{d t} = ω wherein s . θ = ω \qquad Equation 16$$

The result of this integration is an estimated phase angle, as shown by Equation 16:

$$\hat{θ} = \frac{1}{s} \hat{ω} \qquad Equation 17$$

Consequently, the output of block 107 is the estimated phase angle which is fed back for the Park Transformation at block 103, via block 104. The estimated phase angle is also utilised in block 108 to estimate the frequency of the electrical signal in accordance with equation 18:

$$\hat{F} ( k ) = \frac{Δ \hat{θ}}{2 π {T}_{e}} \qquad Equation 18$$

The regulation loop is a discreet process Δθ=θ(k+1)−θ(k)=Te2πF (k). In this loop the angle θ is a continuously increasing ramp; the difference between two successive values of this ramp is divided by the sampling period (Te) and by 2π.

The frequency estimated at block 108 is the estimated frequency fed back to the multi variable band pass filter at block 102.

Using the estimated frequency, the rate of change of the fundamental frequency is then determined for each period of the fundamental frequency. The determination of the rate of change of frequency is carried out at block 109.

The regulation loop described above comprising blocks 101 through to 108 delivers a permanent flow of the estimated fundamental frequency, f(n), f(n+1), f(n+2), at the sampling period of the system. This data is then input into block 109, which then filters the instantaneous data, calculates the average value of the fundamental frequency per cycle and thereby estimates the rate of change of the frequency per cycle. The ratio between the nominal fundamental frequency and the sampling rate determines the number of samples per period: NT. This process is discussed in more detail below.

Firstly, the fundamental frequency is filtered and averaged for each cycle. The nominal number of samples per cycle is NT, abnormal delta positive or negative (for example, +/−2 milliHertz) between two successive estimated values of the fundamental frequencies causes the elimination of the frequency values.

The fundamental frequency is obtained at every sampling period. Since the system cannot have a very fast variation of the frequency between two samples (sampling period being 250 μs to 500 μs) there is a high difference between successive values of the fundamental frequency. This is a sign of an error in the estimation (this difference can be taken: +/−2 milliHertz), and the consequence is that this value is not taken into account.

These estimated values are not taken into account in the next calculations because they are erroneous. Over a cycle, only NT−x values of the fundamental frequency therefore remain, where x is the number of values eliminated on the criteria of abnormal difference between two estimated values. Hence, the average fundamental frequency value (fₐᵥ) is calculated over the cycle with the NT−x remaining values.

The rate of change of frequency per period is estimated by the least squares method giving the average slope

$$\frac{d f ( t )}{d t}$$

among the (Nt−x) validated sampled values of the fundamental frequency as shown by Equation 19:

$$\frac{d f ( t )}{d t} = \frac{Σ Ti . Fi}{Σ {ti}^{2}} \qquad Equation 19$$

Wherein Tᵢ=tᵢ−tₐᵥ and Fᵢ=fᵢ−fₐᵥ, where tᵢ=time of the sample i (i from 1 to NT−x), tₐᵥ is the average value of all the tᵢ, fᵢ is the estimated frequency at sample i (i from 1 to NT−x), and fₐᵥ is the average value of the fundamental frequency over the cycle

Once the frequency and rate of change of frequency are obtained, these values can then be displayed as graphical representations. The graphical representations could then be used by the electricity supply board or direct user. The display processing is performed by block 110. Block 110 could alternatively be performed at a central server based on data received from the smart meter.

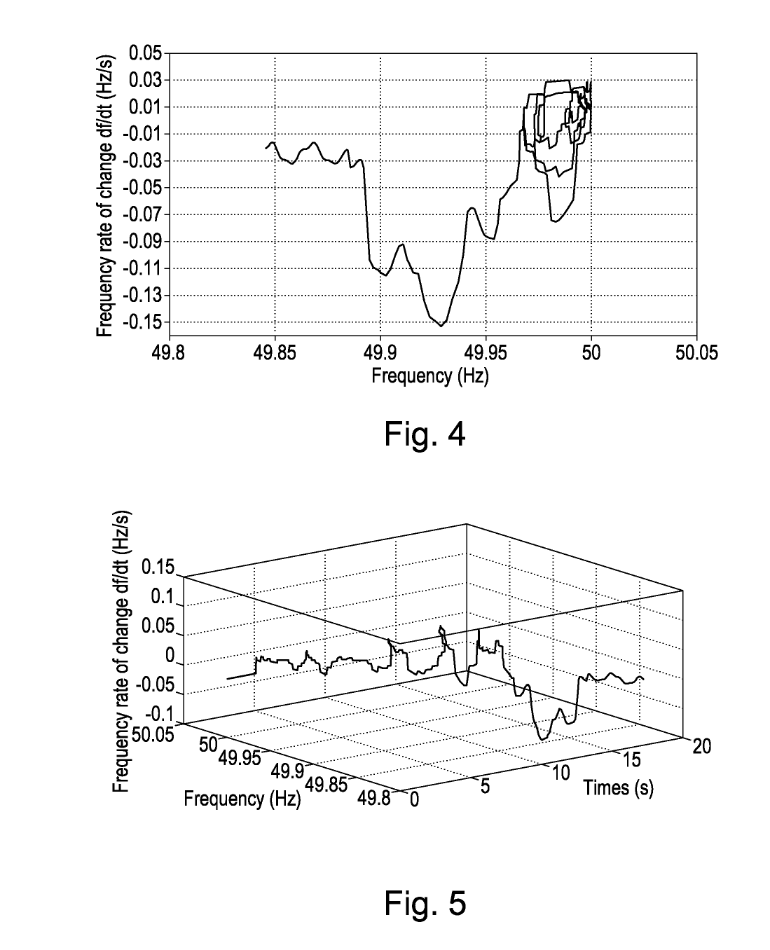

The graphical representations provided by Block 110 include representations of variations in the average fundamental frequency per cycle and the rate of change of the average fundamental frequency per cycle. Such data can be represented in a two dimensional graphic, as shown by FIG. 4, which shows the rate of change of frequency,

$$\frac{d f ( t )}{d t} ,$$

as a function or frequency, f(t), for the excursion of the fundamental frequency for the well-known major European grid disturbance on 4 Nov. 2006 which resulted in a large black-out. FIG. 4 specifically shows the pre-black-out conditions. In addition or alternatively, a three-dimensional graphical representation can be provided as shown in FIG. 5, which illustrates the rate of change of frequency,

$$\frac{d f ( t )}{d t} ,$$

as a function or frequency, f(t), and time, t, for the disturbance on 4 Nov. 2006.

It is also possible, within these graphical representations, to define an alarm boundary at which point it is determined that the fundamental frequency is varying in a dangerous manner. If an alarm boundary is passed then at least part of the grid is shut down to prevent damage to electrical devices connected to the grid system. The alarm boundary can be represented as a maximum limit for the frequency and rate of change of frequency. The alarm therefore acts as a frequency protection relay making disconnection of critical loads of the electrical grid directly by the electricity meter switch possible.

It is also possible to provide a graphical representation of the maximum values of the fundamental frequency and the rate of change of the fundamental frequency per hour or per day. This is known as a time stamped historic record of the maximum values of the fundamental frequency and rate of change of the fundamental frequency.

An example of the implementation of the above-described system shall now be provided.

Experimentation to validate the behavior of the algorithm on a single-phase and a poly-phase network has been done. The experimentation has benchmarked the frequency profile of the UCTE Report of the blackout failure of 4 Nov. 2006.

The signal was reconstituted at 200 μs sampling period over a total interval of 20 seconds. This was therefore a file of 100,000 points per phase and 1,000 cycles. The ratio between the sampling period and the fundamental period is 1/100.

The profile of the fundamental frequency is the reference, the input signals have been intentionally disturbed by unbalanced components for the three phase systems and harmonics.

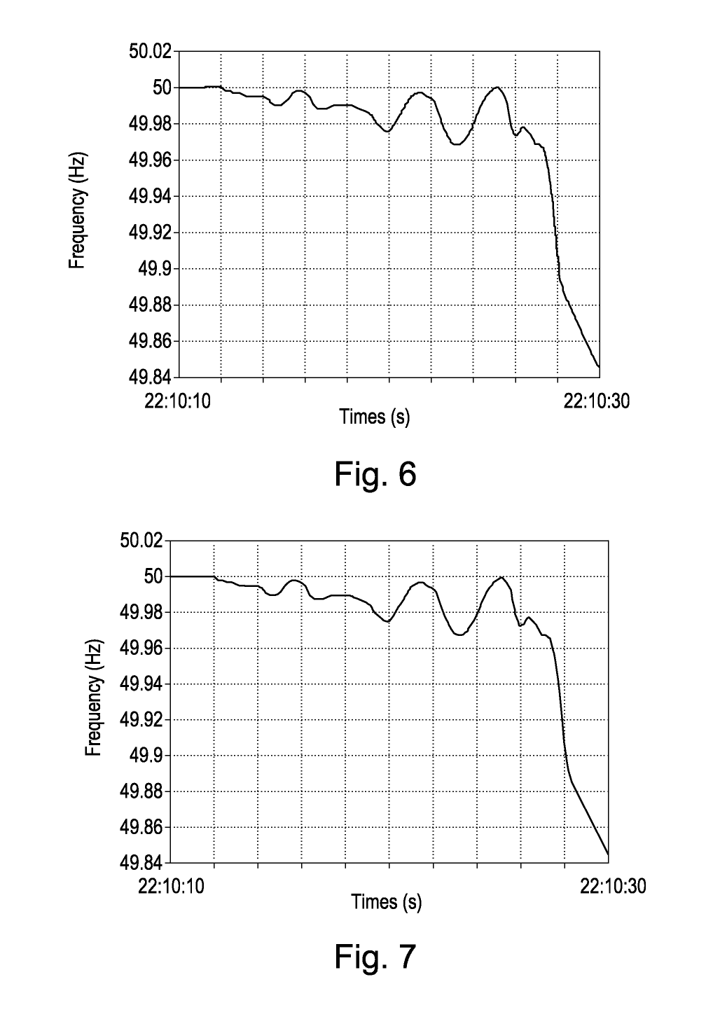

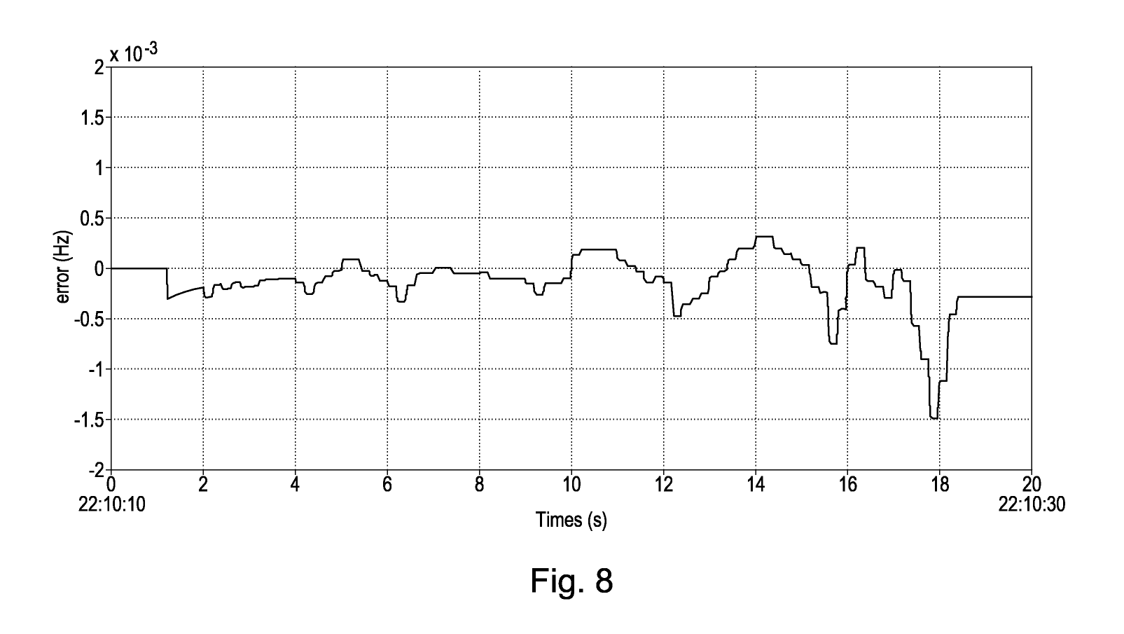

FIG. 6 illustrates computed with the algorithm presented above, while FIG. 7 illustrates the network frequency measured in the field. The error between the field measurement and estimated frequency is shown by FIG. 8. It can therefore be seen that the difference between the field measurement and the estimated frequency is lower than +/−1 millihertz.

For these calculations, a sampling rate of 5 kHz (Te=200 μs) was used, the number of samples per period was around 100, among these NT (100) samples all of the abnormal and therefore erroneous samples were removed between two successive values lower or higher to established limits were eliminated, and then on the remaining samples the average frequency value (fₐᵥ) were calculated. The average frequency value, fₐᵥ is the average value of the fundamental frequency calculated on the remaining Nt−x values over a cycle. This value can be stored as the average value of the fundamental frequency over the cycle.

Per period, the rate of change of frequency was estimated by the least squares method giving the average slope

$$\frac{d f ( t )}{d t}$$

among these 100 samples. Considering the high accuracy of the frequency estimation (+/−1 millihertz) a reliable estimation of the derivative of the fundamental frequency was obtained per fundamental cycle (better than 0.1 Hz per second).

When implemented by a processor on a smart-meter or as a computer program on any type of computer, a computer would be provided having a memory to store the computer program, and a processor to implement the computer program. The processor would then perform the algorithmic process. The computer program may include computer code arranged to instruct a computer to perform the functions of one or more of the various methods described above. The computer program and/or the code for performing such methods may be provided to an apparatus, such as a computer, on a computer readable medium. The computer readable medium could be, for example, an electronic, magnetic, optical, electromagnetic, infrared, or semiconductor system, or a propagation medium for data transmission, for example for downloading the code over the Internet. Non-limiting examples of a physical computer readable medium include semiconductor or solid state memory, magnetic tape, a removable computer diskette, a random access memory (RAM), a read-only memory (ROM), a rigid magnetic disc, and an optical disk, such as a CD-ROM, CD-R/W or DVD.

1. A method for estimating a frequency of an electrical signal, the method comprising:
converting a first signal having three components into a second signal having two components in accordance with a first transformation, wherein each component of the first signal corresponds to a phase component of a three-phase electrical signal and the two components of the second signal are representative of characteristics of the three-phase electrical signal;
filtering the second signal in accordance with a previous frequency estimation;
converting the filtered second signal into a third signal having a single component in accordance with a second transformation, wherein the single component of the third signal is representative of characteristics of the three-phase electrical signal; and
estimating a frequency of the third signal, wherein the estimated frequency of the third signal is indicative of a frequency of the three-phase electrical signal.

2. The method according to claim 1, wherein the filtering comprises applying a band pass filter to the second signal, the band pass filter being centered on the frequency of a previous frequency estimation.

3. The method according to claim 2, wherein the band pass filter is arranged to apply unity gain and zero phase shift at the frequency of the previous frequency estimation.

4. The method according to claim 1, further comprising feeding back the current frequency estimation for filtering the next frequency estimation.

5. The method according to claim 1, wherein the first transformation is a Concordia transformation, as defined by:
$$[ \begin{matrix}{V}_{α} \\ {V}_{β}\end{matrix} ] = \sqrt{\frac{2}{3}} [ \begin{matrix}1 & - \frac{1}{2} & - \frac{1}{2} \\ 0 & \frac{\sqrt{3}}{2} & - \frac{\sqrt{3}}{2}\end{matrix} ] [ \begin{matrix}{V}_{a} \\ {V}_{b} \\ {V}_{c}\end{matrix} ]$$
wherein Vₐ, V_{b}, V_{c} are the three components of the first signal and V_{α} and V_{β} are the two components of the second signal.

6. The method according to claim 1, wherein the second transformation utilizes a previous estimation of a phase of the three-phase electrical signal.

7. The method according to claim 1, wherein the second transformation is a Park transformation, as defined by:
$$[ \begin{matrix}{V}_{d} \\ {V}_{q}\end{matrix} ] = [ \begin{matrix}cos ( \hat{θ} ) & sin ( \hat{θ} ) \\ - sin ( \hat{θ} ) & cos ( \hat{θ} )\end{matrix} ] [ \begin{matrix}{V}_{α} \\ {V}_{β}\end{matrix} ]$$
wherein V_{α} and V_{β} are the two components of the second signal after being filtered, \hat{θ} is a previous estimation of a phase of the three-phase electrical signal, and V_{d} and V_{q} are outputs of the second transformation, wherein V_{d} is forced to zero and V_{q} therefore corresponds to the third signal.

8. The method according to claim 1, wherein the frequency is estimated by:
estimating a phase of the third signal; and
estimating the frequency of the third signal in accordance with the estimated phase.

9. The method according to claim 8, wherein the phase is estimated using a phase locked loop.

10. The method according to claim 9, wherein the phase locked loop comprises a loop filter arranged to estimate an angular frequency of the signal having a single component and a voltage controlled oscillator arranged to estimate the phase of the estimated angular frequency.

11. The method according to claim 8, further comprising feeding back the estimated phase to the second transformation for estimating a next phase.

12. The method according to claim 1, further comprising calculating the average frequency over a period of time, wherein a plurality of frequency estimations are made during the period of time.

13. The method according to claim 12, further comprising determining an error level in the frequency estimation and excluding any frequency estimations from the average frequency calculation having an error level greater than an error threshold.

14. The method according to claim 12, further comprising determining a rate of change of frequency from the average frequency.

15. The method according to claim 1, further comprising measuring the three components of the three-phase electrical signal.

16. The method according to claim 15, wherein the measurement comprises measuring voltages of the three-phase electrical signal.

17. The method according to claim 1, further comprising converting a single-phase electrical signal into the three-phase electrical signal in accordance with a third transformation before converting the three-phase signal in accordance with the first transformation.

18. An apparatus for estimating a frequency of an electrical signal, the apparatus arranged to implement the method of claim 1.

19. The apparatus according to claim 18, wherein the apparatus is an electricity meter.

20. The apparatus according to claim 19, wherein the electricity meter further comprises:
a sensor arranged to measure one or more characteristics of an electrical signal;
a memory arranged to store the one or more characteristics of the electrical signal and store a computer program for implementing the method;
a processor arranged to perform the method in accordance with the stored characteristics of the electrical signal and the computer program; and
a communications unit arranged to transmit information relating to the frequency estimation to a central server.

21. A computer readable medium comprising computer readable code operable, in use, to instruct a computer to perform the method of claim 1.
